(19) United States
(12) Patent Application Publication
(10) Pub. No.: US 2004/0080906 A1
(43) Pub. Date: Apr. 29, 2004

(54) Cable box

(76) Inventor: Eizo Noji, Hiroshima (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 10/673,257

(22) Filed: Sep. 30, 2003

Related U.S. Application Data
(63) Continuation of application No. PCT/JP03/04362, filed on Apr. 4, 2003.

(30) Foreign Application Priority Data
Jun. 17, 2002 (JP) 2002-176137

(51) Int. Cl. H05K 5/00

(52) U.S. Cl. 361/683

(57) ABSTRACT

A cable box of the present invention can safely avoid affecting information transmission cables housed in lower layers, while preventing deformation of synthetic resin inner tubes even in case of extraordinarily high temperature caused by long duration of high load on a power cable.

Metallic radiating plates 11, 12, 13, 14 are transversely arranged, while partition plate 15 is longitudinally placed within foursquare metallic pipe 10, monolithically forming the radiating plates 11, 12, 13, 14, the metallic pipe 10 and partition plate 15 at touching ends to divide the inner space of the metallic pipe 10 into compartments, to house within thus divided compartments foursquare synthetic resin tubes 16, 17a, 17b, 18a, 18b as piled on one another, in order to place the radiating plates 11, 12, 13, 14 on the bottom surface of synthetic resin tubes 17a and 18a where power cables are housed.

### 1. TECHNICAL FIELD

The present invention relates to a cable box and more particularly to a cable box used to lay power cables and information transmission cables such as telephone cables, optical fiber cables, etc.

### 2. BACKGROUND ART

A communal duct for electric wire according to Japanese Patent No. 2987326 by the present inventor is a known cable box used to lay power cables and information transmission cables such as communication cables, optical fiber cables, etc.

This communal duct for electric wire involves buried conduits of metallic pipes coupled to each other. Then, the buried conduit is a foursquare metallic pipe and, in its inner space or in each of large compartments separated by metallic partitions placed in its inner space, synthetic resin-made inner tubes foursquare having one or plural small compartments is fitted. There are plural sizes of synthetic resin-made inner tubes whose longitudinal and transversal length of cross section are as many as the common divisors of the longitudinal and transversal length of cross section of the large compartments respectively. Then, synthetic resin-made inner tubes are composed with one another to be fitted into the large compartments.

Then, the communal conduit for electric wire makes it easy to produce a buried conduit involving a large number of small compartments different in size and shape, not only significantly reducing the labor and costs needed for the production but also giving more freedom in construction of the small compartments to allow a communal conduit for electric wire to be constructed in accordance with specification of a wiring circuit. Moreover, cables there inserted are protected as covered by highly anticorrosive inner tubes to prevent any rust, controlling heat from high voltage power cables, thereby making great improvement in production and exploitation thanks to use of the inner tubes.

However, even in the above conventional communal conduit for electric wire, the inner tube of synthetic resin such as hard vinyl chloride, likely to soften at a temperature of about 80° C., may soften, in case of temporary extraordinarily high temperature (e.g. 100° C.) at the power cable, as heated by long duration of high load on the power cable. Then, the power cable applies its own weight to deform the bottom surface of the inner tube to make it fall, following the shape of the power cable, with a risk of affecting an information transmission cable housed in the lower layer.

Therefore, the purpose of the present invention consists in providing a cable box free from any risk of affecting an information transmission cable housed in a lower layer, without deforming the synthetic resin-made inner tube, even at an extraordinarily high temperature generated by long duration of high load on the power cable.

### 3. DISCLOSURE OF THE INVENTION

Means to solve the problems according to the present invention are as follows.

In the first place, it is a cable box characterized in that metallic radiating plates are transversely arranged inside a foursquare metallic pipe to divide the inner space of the metallic pipe into compartments and house foursquare tubes of synthetic resin as piled one on another within thus divided compartments, in order to place the radiating plate at the bottom of a synthetic resin-made tube that houses a power cable.

Secondly, it is a cable box characterized in that metallic radiating plates are transversely arranged inside a foursquare metallic pipe while partition plates are longitudinally arranged, monolithically forming the radiating plates, the metallic pipe and partition plates at touching ends to divide the inner space of the metallic pipe into compartments and house foursquare synthetic resin-made tubes as piled one on another within thus divided compartments, thereby placing the radiating plates at the bottom of a synthetic resin-made tube that houses a power cable.

In this case, tubes of synthetic resin are usually but not limitedly arranged in two layers arranged one above another, in housing foursquare tubes of synthetic resin as piled one on another within the divided compartments, to house a power cable in the tube of synthetic resin on the lower layer, while housing an information transmission cable in the tube of synthetic resin on the upper layer.

In other words, a power cable can be housed in a tube of synthetic resin on the lowest layer, while housing information transmission cables in the other tubes on the other (middle, upper, etc.) layers, when piled in two or more (e.g. three) layers.

A metallic radiating plate is fixed or inserted mainly at the boundary between a power area and a communication area but can be placed to divide the inner space of the power area into compartments, when piling one on another the very tubes of synthetic resin that house the power cables.

To house foursquare tubes of synthetic resin as piled one on another within separated compartments, the tubes of synthetic resin are usually but not limitedly arranged in two layers to house a power cable in the tube of synthetic resin on the lower layer to call it a power area, while housing an information transmission cable in the tube of synthetic resin on the upper layer to call it a communication area.

Incidentally, in the present invention, the term “power area” indicates a part formed by a tube of synthetic resin to house a power cable, while the term “communication area” means a part formed by a tube of synthetic resin to house an information transmission cable.

Moreover, radiating plates transversely arranged within a metallic pipe can work for thermal dissipation, touching the metallic pipe with both side faces of the radiating plates, thanks to use of rectangular radiating plates dimensioned and shaped so as to touch the transversal inner surface of the metallic pipe.

Such rectangular radiating plates dimensioned and shaped so as to touch the transversal inner surface of the metallic pipe may be fixed beforehand at the metallic tube or may be placed later, without fixation, at the metallic pipe.

To place the radiating plate later at the metallic pipe, the metallic pipe may house two layers of synthetic resin tubes before placing the radiating plate on the upper face of the synthetic resin tube, to house two additional layers of synthetic resin tubes further thereon or may house e.g. four layers of synthetic resin tubes, before inserting the radiating plate in the middle of the four layers piled one on another.

### 4. EFFECT OF THE INVENTION

The cable box of the present invention can safely avoid affecting an information transmission cable housed in a lower layer, without deforming a synthetic resin-made inner tube, even in case of extraordinarily high temperature caused by long duration of high load on a power cable.

### 5. BRIEF EXPLANATION OF DRAWINGS

FIG. 1 is a front view of a cable box with a fixed radiating plate according to the first embodiment of the present invention.

FIG. 2 is a perspective view of a cable box with a fixed radiating plate according to the first embodiment of the present invention.

FIG. 3 is a front view of a cable box with an inserted radiating plate according to the second embodiment of the present invention.

FIG. 4 is a perspective view of a cable box with an inserted radiating plate according to the second embodiment of the present invention.

Reference numerals in the drawings respectively denote the following.

1: Bolt

2: Nut

10: Pipe

11, 12, 13 and 14: Radiating plate

15: Partition plate

16: Large inner tube

17a and 17b: Middle inner tube

18a and 18b: Small inner tube

19: Frame

19a: Pore

20: Pipe

21: Radiating plate

22a and 22b: Inner tube

23: Frame

23a: Pore

### 6. BEST MODE OF REALIZATION The present invention will be explained here below with reference to embodiments that do not restrict the technical scope of the present invention.

Now, an embodiment of the present invention is explained, referring to drawings.

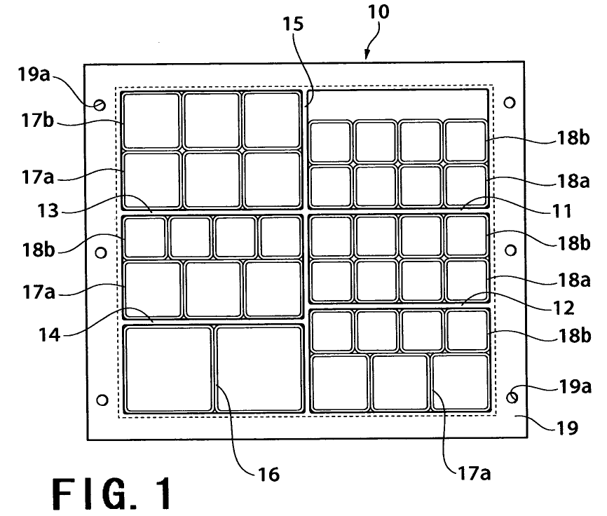

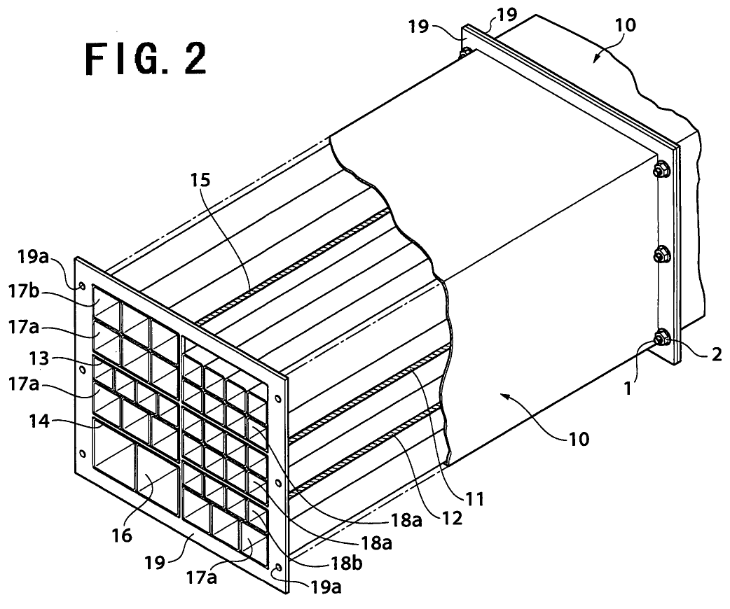

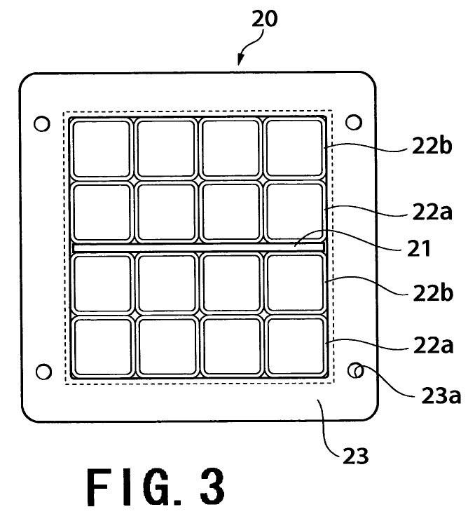

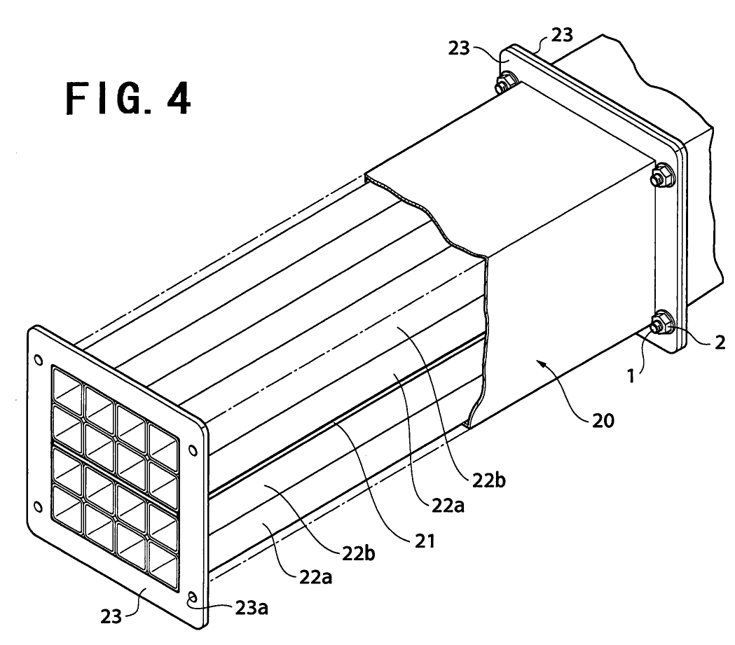

FIG. 1 is a front view of a cable box with a fixed radiating plate according to the first embodiment of the present invention. FIG. 2 is a perspective view of a cable box with a fixed radiating plate according to the first embodiment of the present invention. FIG. 3 is a front view of a cable box with an inserted radiating plate according to the second embodiment of the present invention. FIG. 4 is a perspective view of a cable box with an inserted radiating plate according to the second embodiment of the present invention.

In a cable box with fixed radiating plates of the first embodiment of the present invention, as shown in FIGS. 1 and 2, iron-made radiating plates 11, 12, 13, 14 about 5 mm thick are transversely arranged, while partition plate 15 is longitudinally placed, inside pipe 10 rectangular in cross section, made of iron plates about 6 mm thick to have a width of 60 cm and length of 2 m as a unit, monolithically forming the radiating plates 11, 12, 13, 14, pipe 10 and partition plate 15 at touching ends to fix the respective radiating plates 11, 12, 13, 14 and divide the inner space of pipe 10 into 3 on the right side and 3 on the left side i.e. 6 parts in total.

The present invention may be embodied with not only a cable box as shown in FIGS. 1 and 2 but also a half-type cable box (not illustrated) about 30 cm wide or a cable box (not illustrated) about 0.5 m or 1 m long.

Compartments, thus divided, contain three types of foursquare inner tubes, different in size (large inner tubes 16, middle inner tubes 17a, 17b, small inner tubes 18a, 18b), made from synthetic resin such as hard vinyl chloride, placing only the large tubes 16 in a single layer while the other tubes in two layers or upper and lower layers in the respective compartments.

Then, radiating plates 11, 12, 13, 14 are placed at the bottom of middle inner tube 17a and small inner tube 18a which house power cables.

On the other hand, middle inner tube 17b and small inner tube 18b house information transmission cables such as optical fiber cable.

Each iron plate here is plated with molten zinc for anticorrosion to prevent rust in underground use.

In the drawing, 19 denotes a foursquare frame attached at front and rear ends of pipe 10, while 19a indicates a pore to fix with bolt 1 and nut 2.

Power cables are housed in middle inner tube 17a and small inner tube 18a, while information transmission cables are housed in middle inner tube 17b and small inner tube 18b in the above explanation of large inner tube 16, middle inner tubes 17a, 17b and small inner tubes 18a, 18b. However, a power cable may be housed in middle inner tube 17b in the left uppermost compartment in FIGS. 1 and 2.

In this case, an iron-made radiating plate (not illustrated) about 5 mm thick may be fixed or 1 mm thick may be inserted between middle inner tube 17a to house a power cable and 17b to house a power cable.

In a cable box with an inserted radiating plate according to the second embodiment of the present invention, as shown in FIGS. 3 and 4, iron-made radiating plate 21 rectangular in shape and having a thickness of about 1 mm is inserted and transversely placed inside pipe 20 rectangular in cross section made of iron plates about 6 mm thick to have a width of about 15 cm and a length of about 2 m as a unit in order to divide the inner space of pipe 20 into the upper and lower parts.

The present invention can be realized also with a cable box about 20 cm wide or a cable box about 0.5 m or 1 m long (not illustrated) instead of a cable box such as shown in FIGS. 3 and 4.

In the respective compartments, thus divided, inner tubes 22a, 22b of synthetic resin such as hard vinyl chloride, square in shape, are piled in two layers arranged one on the other in order to place radiating plate 21 at the bottom of inner tube 22a housing a power cable.

Then, inner tube 22b houses an information transmission cable such as an optical fiber cable.

Each iron plate here is plated with molten zinc for anticorrosion to prevent rust in underground use.

In the drawing, 23 denotes a foursquare frame attached at front and rear ends of pipe 20, while 23a indicates a pore to fix with bolt 1 and nut 2.

Now, explanation will e made about the working of the above cable boxes with fixed or inserted radiating plates.

In both of the two types of cable boxes, a radiating plate or the bottom surface of the pipe is placed at the bottom of the inner tube that houses a power cable, allowing the power cable to give more pressure, with its own weight, to touch the bottom.

As a result, the radiating plate, placed at the bottom, radiates more efficiently and can respond to any abnormal heat of the power cable, to prevent the inner tube from being deformed by rise in temperature of the power cable.

Then, a metallic radiating plate and a metallic partition plate, arranged at the boundary between the power area and the communication area, works as a shield to prevent electromagnetic induction to metallic communication cables from being caused by the passage of electric current through the power cable.

1. Cable box characterized in that metallic radiating plates are transversely arranged inside a foursquare metallic pipe to divide the inner space of the metallic pipe and house foursquare synthetic resin-made tubes piled one on another within thus divided compartments, in order to place the radiating plates at the bottom of the synthetic resin-made tubes to house power cables.

2. Cable box characterized in that metallic radiating plates are transversely arranged inside a foursquare metallic pipe while partition plates are longitudinally arranged, monolithically forming the radiating plates, the metallic pipe and partition plates at touching ends to divide the inner space of the metallic pipe into compartments and house foursquare synthetic resin-made tubes piled one on another within thus divided compartments, thereby placing the radiating plates at the bottom of the synthetic resin-made tubes to house power cables.
